(19) United States
(12) Patent Application Publication
(10) Pub. No.: US 2007/0062648 A1
(43) Pub. Date: Mar. 22, 2007

(54) Electrostatic chuck, thin film manufacturing apparatus having the same, thin film manufacturing method, and substrate surface treatment method

(76) Inventors: Shigeru Senbonmatsu, Chiba-shi (JP); Shuhei Yamamoto, Chiba-shi (JP); Mitsuru Suginoya, Chiba-shi (JP); Hideki Matsumura, Ishikawa (JP); Atsushi Masuda, Ishikawa (JP)

Correspondence Address: BRUCE L. ADAMS, ESQ., SUITE 1231, 17 BATTERY PLACE, NEW YORK, NY, 10004, US

(21) Appl. No.: 11/515,650

(22) Filed: Sep. 5, 2006

(30) Foreign Application Priority Data
Sep. 12, 2005 (JP) 2005-263294

(51) Int. Cl. H01L 21/306; H05H 1/24; C23C 16/00

(52) U.S. Cl. 156/345.51; 427/569; 118/728

(57) ABSTRACT

A difficulty has been given, that is, in a condition that an electrostatic chuck having an oxide layer as a dielectric layer is set in catalytic chemical vapor deposition apparatus, as a silicon thin film is repeatedly deposited on a workpiece held by the electrostatic chuck, adsorbing power of the electrostatic chuck is gradually decreased, and finally the chuck does not adsorb a substrate at all. Thus, a dielectric layer on a surface of the electrostatic chuck is covered with an insulating film containing silicon nitride or silicon oxide. Thus, since damage to a chuck surface can be prevented, the damage being due to hydrogen radicals generated during depositing the silicon film by the catalytic chemical vapor deposition apparatus, even if the silicon film is repeatedly deposited, power for adsorbing the substrate is not decreased, and consequently substrate temperature is stabilized during depositing the silicon film.

### BACKGROUND OF THE INVENTION

1. Field of the Invention

The present invention relates to an electrostatic chuck used in a thin film manufacturing method or a substrate surface treatment method, and particularly relates to an electrostatic chuck that can used for a long period without decreasing adsorbing power even in a high temperature atmosphere containing hydrogen radicals during manufacturing a silicon thin film and the like.

2. Description of Related Art

In electrostatic chucks in the related art, while various insulators have been proposed for a dielectric layer on a chuck surface, particularly an oxide such as Al₂O₃ or MgO is typically used for the dielectric layer in the light of adsorbing power at high temperature or controllability of a thermal expansion coefficient (preventability of cracks due to difference in thermal expansion coefficient between bonded surfaces (for example, refer to JP-A-2004-311522 (patent literature 1).

The electrostatic chuck in the related art has been introduced into a semiconductor process particularly for dry etching using fluorine radicals in the semiconductor process. On the other hand, a catalytic chemical vapor deposition process has been proposed as a chemical vapor deposition process without causing plasma damage and increasingly noted as an effective approach for forming a silicon thin film. However, since the catalytic chemical vapor deposition process is a process of generating a deposition species through a reaction of a catalyst and a source gas which have been heated and depositing the species on a substrate, a difficulty has been given, that is, substrate temperature is steeply increased during deposition due to influence of radiant heat from the catalyst, thereby substrate surface temperature is not uniform during deposition, and consequently film quality is varied in a thickness direction. As a solution to prevent steep increase of the substrate surface temperature, a method has been disclosed, in which the substrate is adsorbed by a temperature-controllable electrostatic chuck, thereby steep increase in substrate temperature due to radiant heat from the catalyst is controlled during deposition. This is described in a document of a product debrief session of NEDO Academia Alliance Industrial Science Technology Research and Development Project, Semiconductor Device Manufacturing Process Using Cat-CVD Process, Jun. 4, 2001, pp 19 to 22, FIGS. 7 and 8 (non-patent literature 1).

However, it was known that when the electrostatic chuck using the oxide such as Al₂O₃ or MgO for the dielectric layer was set in catalytic chemical vapor deposition apparatus, and a silicon thin film such as a thin film of amorphous silicon or polysilicon was repeatedly deposited using SiH₄ and H₂ as a source gas at a temperature of the electrostatic chuck of 400° C., adsorbing power of the electrostatic chuck was gradually decreased, and finally the chuck did not adsorb the substrate at all. As a result of investigating the electrostatic chuck of which the adsorbing power was decreased, it was known that a resistance value of a surface of the electrostatic chuck was significantly decreased. Furthermore, it was known from composition analysis of the surface that the oxide in the surface of the electrostatic chuck was reduced.

Moreover, a method has been disclosed, in which a thin insulating film is coated on a surface of the electrostatic chuck including a layer of a dielectric such as Al₂O₃ added with chromium oxide and titanium oxide to prevent heavy metal contamination of the substrate by chromium and titanium (for example, refer to JP-A-7-74233 (patent literature 2)). The thin insulating film includes elements among Al, Si, O, N, and H, and for example, Al₂O₃, AlN, SiO₂, Si₃N₄, and a-Si—H can be used. Since the thin insulating films were coated on the electrostatic chuck for the purpose of preventing the heavy metal contamination of the substrate, materials of the insulating films were complicatedly varied. For example, even if the Al₂O₃ was coated on the electrostatic chuck, when the silicon thin film was repeatedly deposited by the catalytic chemical vapor deposition process, a trouble occurred, that is, a thin oxide film on the surface of the electrostatic chuck was reduced, resulting in significant decrease in power for adsorbing the substrate.

There was a difficulty that when the electrostatic chuck using the oxide such as Al₂O₃ or MgO for the dielectric layer was set in the catalytic chemical vapor deposition apparatus, and the silicon thin film such as the thin film of amorphous silicon or polysilicon was repeatedly deposited using SiH₄ and H₂ as the source gas at the temperature of the electrostatic chuck of 400° C., adsorbing power of the electrostatic chuck was gradually reduced, and finally the chuck did not adsorb the substrate at all.

As a result of investigating the electrostatic chuck of which the adsorbing power was reduced, it was known that the resistance value of the surface of the electrostatic chuck was significantly decreased. Furthermore, it was known from the composition analysis of the surface that the oxide in the surface of the electrostatic chuck was reduced.

It is known that the deposition species when the silicon film is deposited using SiH₄ and H₂ as the source gas by using the catalytic chemical vapor deposition process has many hydrogen radicals compared with that in other chemical vapor deposition processes. Here, only the H₂ gas was introduced into the catalytic chemical vapor deposition apparatus, and a surface of an electrostatic chuck of which adsorbing power was not been reduced was treated for 10 min by hydrogen radicals formed by thermal decomposition of the H₂ gas, as a result, it was known that the oxide on the surface of the electrostatic chuck was reduced by the hydrogen radicals. In particular, when the electrostatic chuck was set at high temperature of 300° C. or more, a reduction reaction was able to be significantly found. FIG. 4 shows a result of investigating adsorbing power of the electrostatic chuck against applied voltage before and after the hydrogen radical treatment. It is known from FIG. 4 that when the hydrogen radical treatment is performed to the surface of the electrostatic chuck, the power for adsorbing the substrate is significantly decreased.

A reduced top of the electrostatic chuck is polished, thereby the power for adsorbing the substrate can be recovered because a chuck surface of an original unreduced oxide is exposed. However, the electrostatic chuck needs to be once removed before being polished by a polisher in order to improve surface smoothness. Therefore, load in maintenance becomes large, and actually the electrostatic chuck has not been able to be used for the catalytic chemical vapor deposition apparatus except for a process in an experimental level on a small scale.

Thus, insulating films of various materials were coated on the surface of the electrostatic chuck, and a durability test of the electrostatic chuck was repeatedly performed, as a result, it was found that coatings of particular insulating films were excellent insulating films, which stood for repeated deposition of the silicon thin film by the catalytic chemical vapor deposition process, and consequently an embodiment of the invention was made.

### SUMMARY OF THE INVENTION

An electrostatic chuck of the embodiment of the invention, which is used for adsorbing the substrate in a hydrogen-containing radical atmosphere, includes a dielectric layer containing an oxide layer and an insulating film for covering the dielectric layer, wherein the insulating film contains at least one of silicon oxide and silicon nitride. The electrostatic chuck having such a configuration can prevent decrease in power for adsorbing the substrate even if it is used for adsorption of the substrate in the hydrogen-containing radical atmosphere.

Furthermore, the dielectric layer contains at least one of aluminum oxide and magnesium oxide. Furthermore, the insulating film is formed using a chemical vapor deposition process or a physical vapor deposition process.

Moreover, thin film manufacturing apparatus of the embodiment of the invention has the electrostatic chuck having the dielectric layer containing an oxide and the insulating film for covering the dielectric layer, a supply mechanism for supplying a gas containing the hydrogen element, and a decomposition mechanism for decomposing the gas, wherein the insulating film contains at least one of the silicon oxide and the silicon nitride. The apparatus is configured such that a deposition species formed through decomposition by the decomposition mechanism is deposited on the electrostatic chuck.

Furthermore, a thin film manufacturing method of the embodiment of the invention has a step of adsorbing the substrate using the electrostatic chuck in any one of configurations as above, a step of supplying a source gas containing the hydrogen element into a chamber having the substrate disposed therein, and a step of generating a deposition species by decomposing the source gas and thus forming a thin film on a surface of the substrate. Furthermore, a substrate surface treatment method of the embodiment of the invention has a step of adsorbing the substrate using the electrostatic chuck in any one of the configurations, a step of supplying a treatment gas containing the hydrogen element into the chamber having the substrate disposed therein, and a step of generating a treatment species by decomposing the treatment gas and thus treating the surface of the substrate. In the thin film manufacturing method or the substrate surface treatment method, the source gas or the treatment gas can be decomposed by the catalytic chemical vapor deposition process. Alternatively, the source gas or the treatment gas can be decomposed by the plasma assist chemical vapor deposition process.

### BRIEF DESCRIPTION OF THE DRAWINGS

FIGS. 1A to 1C are schematic views for illustrating an electrostatic chuck of an embodiment of the invention;

FIG. 2 is a schematic view showing a configuration of apparatus of the embodiment of the invention;

FIG. 3 is a schematic view for illustrating a catalyst used in the embodiment of the invention;

FIG. 4 is a graph showing a relationship between power for adsorbing a substrate of an electrostatic chuck and applied voltage in the related art; and

FIG. 5 is a graph showing a relationship between power for adsorbing a substrate of an electrostatic chuck and applied voltage in the embodiment of the invention.

### DETAILED DESCRIPTION OF THE PREFERRED EMBODIMENT

In an electrostatic chuck of an embodiment of the invention, the dielectric layer on a surface of the chuck is covered by the insulating film containing the silicon oxide or the silicon nitride. In a catalytic chemical vapor deposition process using the electrostatic chuck of the embodiment of the invention, since damage to the chuck surface due to a large amount of hydrogen radicals generated during depositing the silicon film using SiH₄ and H₂ as the source gas, even if the silicon film is repeatedly deposited, the power for adsorbing the substrate is not decreased, and consequently substrate temperature is stabilized for a long period during depositing the silicon film.

Hereinafter, the electrostatic chuck, a thin film manufacturing method, and a substrate surface treatment method are described in detail according to drawings.

### Embodiment 1

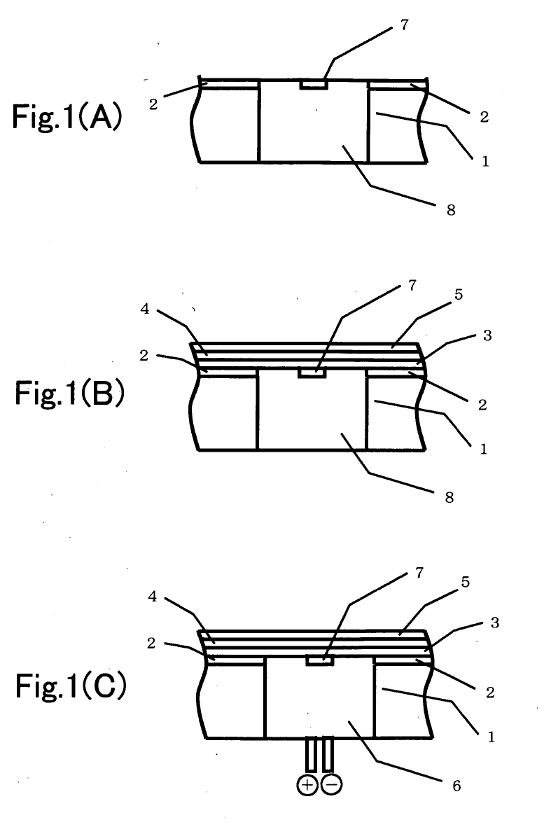

The electrostatic chuck of the embodiment of the invention is described using FIGS. 1A to 1C. A first dielectric layer 2 including the aluminum oxide was thermally sprayed on an aluminum substrate 1 having a cavity in a central portion, and then an electrode 7 as a conductor was set in the cavity in the central portion together with a jig 8 (FIG. 1A). Then, an internal electrode 3 made of tungsten was thermally sprayed thereon to electrically connect between the electrode 7 and the internal electrode 3, and then the aluminum oxide is thermally sprayed for a second dielectric layer 4. While the aluminum oxide was used for the second dielectric layer here, the magnesium oxide may be used. Furthermore, a silicon nitride film was formed by the chemical vapor deposition process as an insulating film 5 on the second dielectric layer 4 (FIG. 1B). A film containing the silicon nitride or the silicon oxide can be used for the insulating film 5 in addition to the silicon nitride film. Finally, the jig 8 was removed, and a power terminal portion 6 was brazed for externally supplying voltage to the internal electrode 3 (FIG. 1C). While omitted to be shown, the electrostatic chuck of the example has the hyperbolic internal electrode 3, and has a heater for heating the substrate within the chuck.

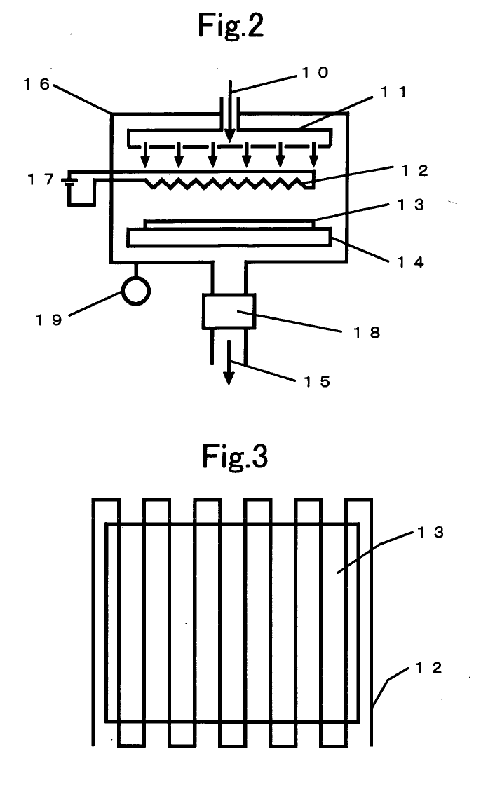

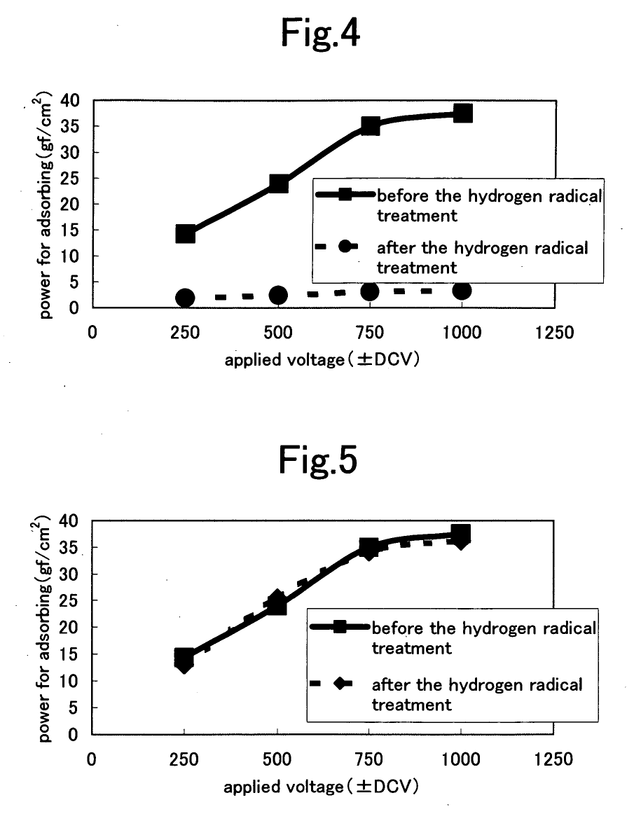

Catalytic chemical vapor deposition apparatus is described using FIGS. 2 and 3 as an example of thin film manufacturing apparatus in which an electrostatic chuck 14 of the example is set. FIG. 2 is a schematic view showing a configuration of the catalytic chemical vapor deposition apparatus. The inside of a vacuum chamber 16 is kept at a high vacuum by evacuation 15 using a vacuum pump, and a degree of vacuum is measured by a vacuum gage 19. An automatic pressure control mechanism 18 is provided in an evacuation system, which controls evacuation speed to keep gas pressure in the vacuum chamber 16 constant while monitoring the pressure using the vacuum gage 19 in the chamber 16. A source gas 10 having a flow rate accurately controlled via a mass flow controller is supplied from a shower head 11 into the vacuum chamber 16. A catalyst 12 for decomposing the source gas 10 is provided near a nozzle portion of the shower head 11. To heat the catalyst 12, power is supplied from a power source 17 to the catalyst 12. Furthermore, the electrostatic chuck 14 for adsorbing the substrate 13 has a mechanism that can control temperature of the chuck to be any temperature below 500° C. Moreover, a treatment gas can be supplied instead of the source gas 10 by changing a not-shown valve.

FIG. 3 schematically shows a shape of the catalyst 12. As shown in the figure, the catalyst 12 of the example is formed parallel to a surface of the substrate and uniformly on the surface using a tungsten wire 0.5 mm in diameter. A tension mechanism for keeping the shape of the catalyst 12 is omitted to be described.

Here, while the substrate 13 was adsorbed in a condition that temperature of the electrostatic chuck 14 was 400° C. and applied voltage was ±1000 V, and a silicon thin film was repeatedly deposited using SiH₄ and H₂ as the source gas 10 at the temperature of the catalyst 12 of 1800° C. here, the adsorbing power of the electrostatic chuck 14 was not decreased. Moreover, in a condition that the temperature of the electrostatic chuck 14 was 300° C., H₂ as a treatment gas was used instead of the source gas 10, and the temperature of the catalyst 12 was 1200° C., hydrogen radical treatment was performed to a top of the electrostatic chuck for 10 min without setting the substrate 13, so that change in adsorbing power of the electrostatic chuck 14 with time was investigated. The result is shown in FIG. 5. From FIG. 5, it is known that even if the hydrogen radical treatment is performed, the adsorbing power of the electrostatic chuck 14 of the example is not decreased within a range of applied voltage of ±250 V to ±1000 V.

While resistance to hydrogen radicals of the electrostatic chuck was experimentally verified directly without placing the substrate 13 in the example, the electrostatic chuck of the embodiment of the invention is adaptable for other thin film manufacturing methods or substrate surface treatment methods which may generate hydrogen radicals without limiting to the catalytic chemical vapor deposition apparatus.

### Embodiment 2

When the electrostatic chuck 14 described in the example 1 is used in the catalytic chemical vapor deposition apparatus, the electrostatic chuck 14 is set in the catalytic chemical vapor deposition apparatus, and then a silicon nitride film can be deposited on the second dielectric layer 4 by the catalytic chemical vapor deposition apparatus. Moreover, while the adsorbing power of the electrostatic chuck 14 was gradually decreased with use of the chuck for a considerably long period, when the adsorbing power was decreased, a silicon nitride film was re-deposited on the surface of the electrostatic chuck 14 by the catalytic chemical vapor deposition apparatus, thereby the adsorbing power was able to be easily recovered. Since the adsorbing power can be easily recovered without removing the electrostatic chuck having decreased adsorbing power for re-polishing, an advantage is given by the embodiment of the invention, that is, an electrostatic chuck having excellent practicability can be provided. While the catalytic chemical vapor deposition apparatus is used as an example in the example here, the electrostatic chuck can be used in the plasma assist chemical vapor deposition apparatus or other types of chemical vapor deposition apparatus or physical vapor deposition apparatus.

According to the catalytic chemical vapor deposition apparatus having the electrostatic chuck of the embodiment of the invention set therein, even if the silicon film is repeatedly deposited, the power for adsorbing the substrate is not decreased because the surface of the electrostatic chuck is not reduced. Accordingly, since steep temperature rise of the substrate due to radiant heat from the heated catalyst can be controlled during depositing the silicon thin film, an advantage is given, that is, a silicon film having uniform film quality in a thickness direction can be deposited stably for a long period.

According to the thin film manufacturing method using the electrostatic chuck of the embodiment of the invention, an excellent silicon thin film used for a TFT liquid crystal display or a thin film silicon solar cell can be deposited. Moreover, the substrate surface treatment method using the electrostatic chuck of the embodiment of the invention is effective for modification of a substrate surface, treatment for decreasing defects of a silicon thin film, or removal of organic substances using hydrogen radicals.

What is claimed is:

1. An electrostatic chuck used for adsorbing a substrate in a hydrogen-containing radical atmosphere, the chuck comprising:
a dielectric layer containing an oxide, and
an insulating film for covering the dielectric layer,
wherein the insulating film contains at least one of silicon oxide and silicon nitride.

2. The electrostatic chuck according to claim 1:
wherein the dielectric layer contains at least one of aluminum oxide and magnesium oxide.

3. The electrostatic chuck according to claim 1:
wherein the insulating film is formed by a chemical vapor deposition process or a physical vapor deposition process.

4. Thin film manufacturing apparatus comprising:
an electrostatic chuck having a dielectric layer containing an oxide and an insulating film for covering the dielectric layer,
a supply mechanism for supplying a gas containing the hydrogen element, and
a decomposition mechanism for decomposing the gas,
wherein the insulating film contains at least one of silicon oxide and silicon nitride.

5. The thin film manufacturing apparatus according to claim 4:
wherein the apparatus is configured such that a deposition species formed through decomposition by the decomposition mechanism is deposited on the electrostatic chuck.

6. A thin film manufacturing method comprising:
adsorbing a substrate using an electrostatic chuck in a configuration having a dielectric layer containing an oxide, and an insulating film containing at least one of silicon oxide and silicon nitride, for covering the dielectric layer,
supplying a source gas containing the hydrogen element into a chamber having the substrate disposed therein, and
generating a deposition species by decomposing the source gas and thus forming a thin film on a surface of the substrate.

7. The thin film manufacturing method according to claim 6:
wherein the source gas is decomposed by a catalytic chemical vapor deposition process.

8. The thin film manufacturing method according to claim 6:
wherein the source gas is decomposed by a plasma assist chemical vapor deposition process.

9. A substrate surface treatment method comprising:
adsorbing a substrate using an electrostatic chuck in a configuration having a dielectric layer containing an oxide, and an insulating film containing at least one of silicon oxide and silicon nitride, for covering the dielectric layer,
supplying a treatment gas containing the hydrogen element into a chamber having the substrate disposed therein, and
generating a deposition species by decomposing the treatment gas and thus treating a surface of the substrate.

10. The substrate surface treatment method according to claim 9:
wherein the source gas or the treatment gas is decomposed by a catalytic chemical vapor deposition process.

11. The substrate surface treatment method according to claim 9:
wherein the source gas or the treatment gas is decomposed by a plasma assist chemical vapor deposition process.
